(19) United States
(12) Patent Application Publication
(10) Pub. No.: US 2011/0063934 A1
(43) Pub. Date: Mar. 17, 2011

(54) MEMORY CIRCUIT WITH MULTI-SIZED SENSE AMPLIFIER REDUNDANCY

(75) Inventors: Vibhu Sharma, Leuven (BE); Stefan Cosemans, Mol (BE); Wim Dehaene, Kessel-Lo (BE)

(73) Assignees: Stichting IMEC Nederland, Eindhoven (NL); Katholieke Universiteit Leuven, Leuven (BE)

(21) Appl. No.: 12/879,972

(22) Filed: Sep. 10, 2010

Related U.S. Application Data
(60) Provisional application No. 61/241,825, filed on Sep. 11, 2009.

(51) Int. Cl. G11C 7/08

(52) U.S. Cl. 365/207

(57) ABSTRACT

A memory circuit with multi-sized sense amplifier redundancy is disclosed. In one aspect, the circuit includes sense amplifiers connected to differential bit-lines and configured to amplify a voltage difference sensed on the differential bit-lines. The sense amplifiers include a first set of smaller sense amplifiers and a second set of larger sense amplifiers redundantly arranged to the first set to form redundant groups which each contain one smaller sense amplifiers and one larger sense amplifiers. The larger sense amplifiers have a failure rate lower than the smaller sense amplifiers. The circuit also includes calibration circuitry connected to enable and disable nodes of each of the sense amplifiers and configured to select for each redundant group either the smaller sense amplifier of the first set or, if the smaller sense amplifier fails, the larger sense amplifier of the second set.

### CROSS REFERENCE TO RELATED APPLICATIONS

This application claims priority under 35 U.S.C. §119(e) to U.S. provisional patent application 61/241,825 filed on Sep. 11, 2009, which application is hereby incorporated by reference in its entirety.

### BACKGROUND OF THE INVENTION

1. Field Of The Invention

The present invention relates to memory design and related low power optimization techniques. More particularly, the present invention relates to methods for reducing power consumption in SRAM designs by applying size-based redundancy techniques for sense amplifiers.

2. Description of the Related Technology

The performance of sense amplifiers in memory circuits, especially with small signal sensing amidst intra- and inter-die variations becomes severely restricted with shrinking technology nodes. It becomes a vital constraint to be resolved for designing ultra low energy memories with long word length in DDSM technologies.

Redundancy is a powerful technique for managing variation in ultra-low-voltage systems. In sense amplifiers, redundancy eases the trade-off between physical area and probability of error in sensing due to offset variation. Instead of a single full size sense-amplifier, N smaller copies can be created within the same area [4]. Due to their smaller devices, these redundant copies exhibit wider offset distributions. However, the overall error probability is now the probability that all N sense-amplifiers fail.

Design of sense amplifiers (SA) with low input swing signal for enabling ultra low energy read operation in SRAM is limited by the offsets of SA transistors. Upsizing the transistors [3] in order to mitigate these offsets directly maps into increased energy of the SA.

### SUMMARY OF CERTAIN INVENTIVE ASPECTS

Certain inventive aspects relate to a memory circuit showing a reduced power consumption.

In one aspect, a variation on SA redundancy is presented. Compared to traditional memory design, in which a single SA per global bit line is designed for a certain failure rate fᵣ, the single SA is replaced with several different sized SAs which may collectively have the same or a less failure rate fᵣ. By selecting a good combination of sizes the energy consumption and the chances of failure can be decreased. Using this technique energy can be minimized for a target yield.

Offsets of a SA are the result of global and local variation in their devices. The impact of global variations can be mitigated by using a differential architecture for the SA. However, to guard against local variations, amidst low input signal sensing, a larger SA may be needed. Scaling up a SA however directly leads to an increased dynamic energy consumption. This can drastically increase the read energy for SRAM when the word length is long. This problem can be overcome by using N different sized SA on each global bit-line. In one aspect, each global bit-line is connected to N SAs of different sizes instead of single SA, and a calibration is performed to evaluate for each bit-line the smallest among the SAs which does not fail.

In one aspect, the calibration circuitry of the memory circuit comprises a register for storing per bit-line the selection of which among the SAs is to be used.

### BRIEF DESCRIPTION OF THE DRAWINGS

The invention will be further elucidated by means of the following detailed description and the accompanying drawings.

FIG. 1 shows the principle of multi-sized SA redundancy used in memory circuits according to one embodiment.

FIG. 2 shows a comparison of one embodiment with prior art calibration techniques.

FIG. 3 shows the optimal results for asymmetric SA redundancy with N=2, with energy and area normalized to those of a traditional SA with identical input signal and fᵣ.

FIG. 4 shows the optimal results for asymmetric SA redundancy with N=3, with energy and area normalized to those of a traditional SA with identical input signal and fᵣ.

FIG. 5 shows the optimal results for asymmetric SA redundancy with N=4, with energy and area normalized to those of a traditional SA with identical input signal and fᵣ.

FIG. 6 shows a part of an embodiment of a memory circuit with 2 different sized SAs (n₁=2-sigma, n₂=6-sigma).

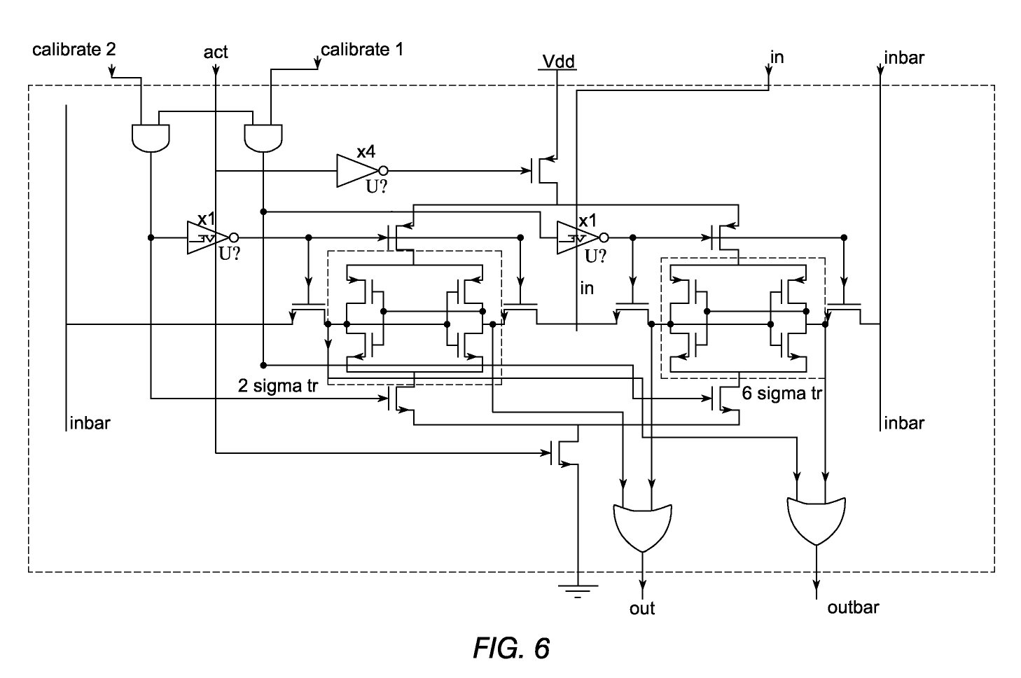

FIG. 7 shows the redundant SA organization for N=2 with n₁=2-sigma n₂=6-sigma for memory word length of 64 bits.

FIG. 8 shows an embodiment of a memory architecture.

FIG. 9 shows an overview and the operation of a local bit-slice of the memory architecture of FIG. 8 during a read operation.

### DETAILED DESCRIPTION OF CERTAIN ILLUSTRATIVE EMBODIMENTS

As used herein, “yield” is intended to mean the semiconductor fabrication yield, i.e. the proportion of devices produced in a semiconductor fabrication process which function correctly. The yield is expressed as a multiple of “sigma”, for example a six-sigma process is one in which 99.99966% of the products manufactured are statistically expected to be free of defects (3.4 defects per million).

As used herein, “failure rate” is intended to mean the proportion of devices which fail. The failure rate is inversely proportional to the yield.

As used herein, “differential bit-line” is intended to mean a pair of bit-lines wherein one is the electronic counterpart with respect to the other. For example, if the one is set to a logical “1”, the other is set to a logical “0” and vice versa.

A sense amplifier (SA) is a circuit that resolves a small input voltage difference applied to its input terminals to a full voltage level output. The READ sense amplifier is designed to sense low voltage swing on the input terminals. The smaller the swing that can be resolved by the sense amplifier, the lesser the energy consumption involved in charging and discharging large capacitance associated with the bit-lines. A better sense amplifier design also reduces the memory access time, as an accessed cell has to develop a smaller swing.

Ultra low energy SRAM's for L1 data/instruction memory are becoming increasingly vital to meet the energy limitations of the energy scavenging wireless sensor nodes. Herein, it is shown that multi-sized SA redundancy can be used for the global read sense amplifiers (GSA) to accommodate process variation and achieve an ultra low energy access for the target yield.

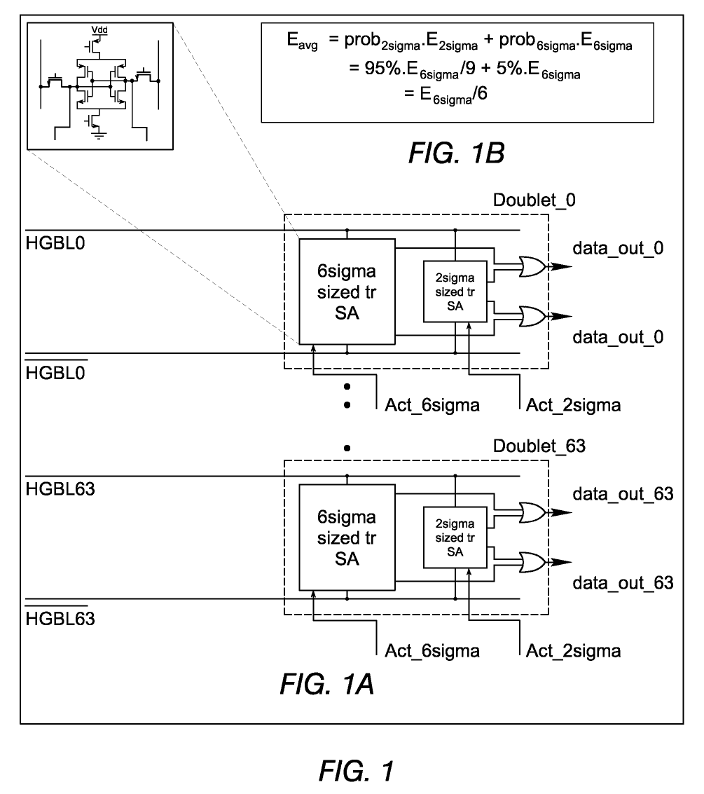

The design of global read sense amplifiers is critical to achieve the low energy target at an acceptable yield. The minimal global bit line (GBL) swing that can be resolved reliably is limited by the offset of the SA caused by intra die transistor variations. In traditional SA design this offset is reduced by increasing the size of the critical transistors [3], which directly maps into increased dynamic energy consumption. This is becoming quite problematic, especially for memories with large word length designed in DDSM technologies. According to one embodiment, the problem is remedied by using multi-sized SA redundancy which is different from traditional SA redundancy [4]. In the traditional memory design there is a single SA per global bit line designed for a certain failure rate fᵣ. In [4] this single SA is replaced by set of N equal sized smaller SAs. There is a separate calibration phase to find a working SA from the set. Then only this selected SA is activated during the READ operation. In multi-sized SA redundancy, which is the principle of one embodiment (FIG. 1a), the single global SA is replaced with a set of different sized SAs, which may collectively have the same or even less fᵣ with respect to the prior art single SA devices. By using a good combination of sizes both the energy consumption and the chances of failure can be reduced.

### a) General Description of Certain Embodiments

When energy is more important than area, it is beneficial to use different sizes for the SAs. For example, assume a setup with one small SA SA1 and one big SA SA2. If the small SA is designed with an allowed failure rate of fᵣ₁=5%, its nfᵣ₁≈2, and its energy consumption is about (6/2)²=9 times smaller than that of a SA that is designed for a failure rate of 2·10⁻⁹. If the redundant SA is designed for this very small failure rate, the combination will work almost for sure. On average (over many different instances), the energy consumption will be

$$\begin{matrix}{E}_{avg} = {p}_{1} \cdot {E}_{1} + {p}_{2} \cdot {E}_{2} \\ = 95 \% \frac{{E}_{big}}{9} + 5 \% {E}_{big} \\ = 0.16 {E}_{big}\end{matrix} \qquad Equation 1$$

Even with these random choices, the average energy consumption is lower than for symmetrical SA redundancy with N=4. Below, a more complete description of asymmetric SA redundancy is presented.

N redundant SAs are used, with failure rates fᵣ₁ . . . f_{rN}. The indices are sorted on SA size so that the smallest SA has index 1. The failure rate after applying redundancy, fᵣ, is

$$fr = P [ all N SAs fail ] = {\prod }_{i = 1}^{N} {fr}_{i} \qquad Equation 2$$

For our example with N=2, fᵣ=2·10⁻⁹ and fᵣ1=5%, we should use fᵣ₂=(fᵣ/fᵣ₁)=4·10⁻⁸. This means that n₂=5.5 instead of n₂=6.1.

The probability that SA i of a redundant group is used, is called pi. If the smallest SA works, it will be used:

p₁=P[SA₁works]=1−P[SA₁fails]=1−fr₁ Equation 3

The second SA is used only if it works correctly and the first SA does not work. These events are assumed to be independent, so

$$\begin{matrix}{p}_{2} = P [ {SA}_{1} fails \& {SA}_{2} works ] \\ = P [ {SA}_{1} fails ] \cdot P [ {SA}_{2} works ] \\ = {fr}_{1} \cdot ( 1 - {fr}_{2} )\end{matrix} \qquad Equation 4$$

In general, the i^{th} SA is used if all small SAs fail and the i^{th} SA itself works correctly.

$${P}_{i} = ( {\prod }_{j = 1}^{i - 1} {fr}_{j} ) \cdot ( 1 - {fr}_{i} ) \qquad Equation 5$$

These probabilities do not add up to 1, as there is still a probability fᵣ that there is no working SA in the redundant group. In the following graphs, this remaining failure probability fᵣ is added to p_{N}, the probability that the largest SA is used.

$${p}_{N} = 1 - ( {\sum }_{j = 1}^{N - 1} {fr}_{j} ) \qquad Equation 6$$

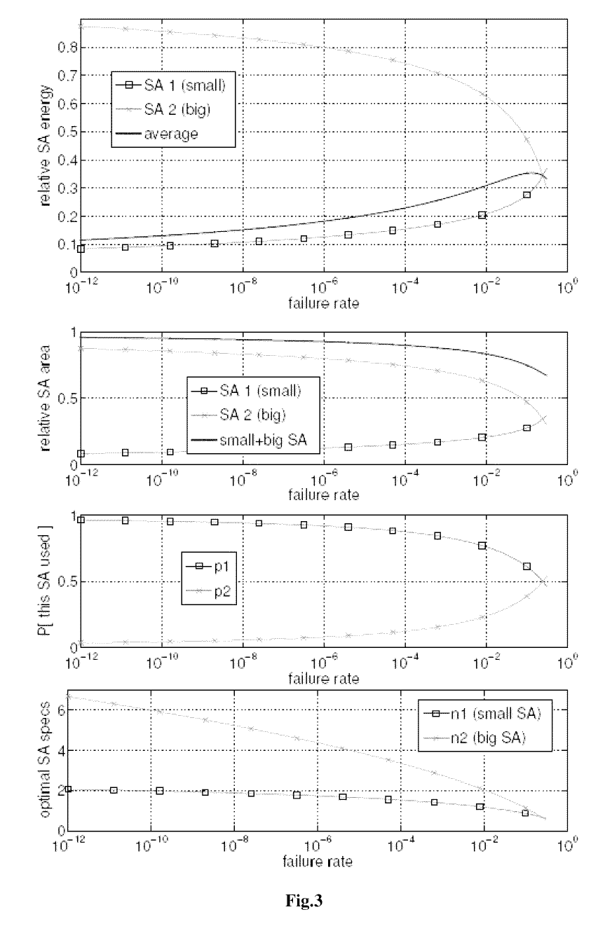

FIG. 3 shows the results of a numerical optimization for N=2. For each fᵣ, a sweep over all possible values for fᵣ₁ is performed, the corresponding fᵣ₂ is obtained from equation 6. The value of fᵣ₁ that minimizes E_{avg} was selected. The area consumption is slightly smaller than for a traditional SA if the calibration overhead can be ignored. The energy consumption can be significantly reduced. At fᵣ=10⁻⁹, the relative energy consumption is 0.14, comparable to symmetrical redundancy with N=5 (ignoring overhead).

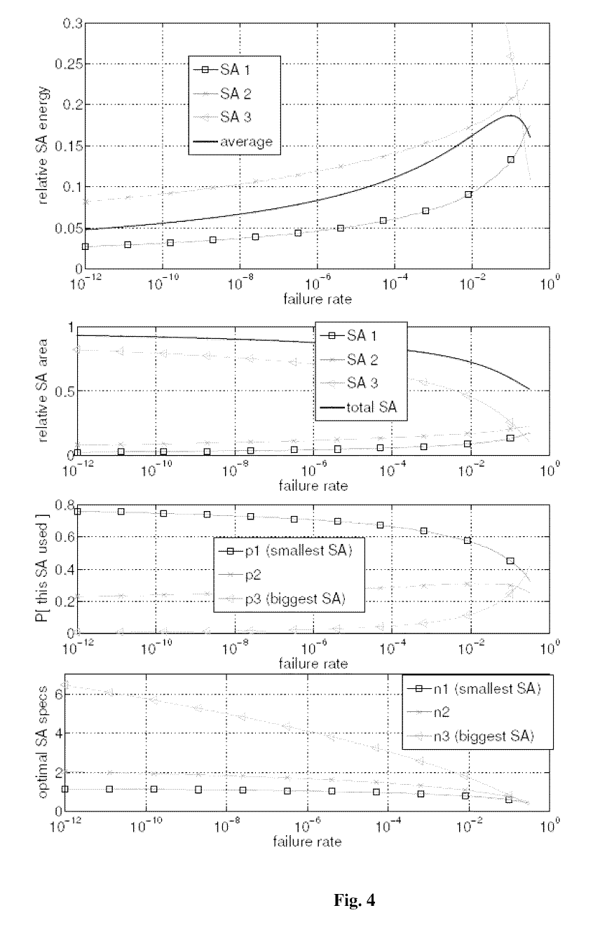

The same exercise was performed for N=3. In this case, a sweep is performed over fᵣ₁ and fᵣ₂, and fᵣ₃ is obtained from equation 6. The results are shown in FIG. 4. At fᵣ=10⁻⁹, the relative energy consumption is 0.061, comparable to symmetrical redundancy with N=10 (ignoring overhead).

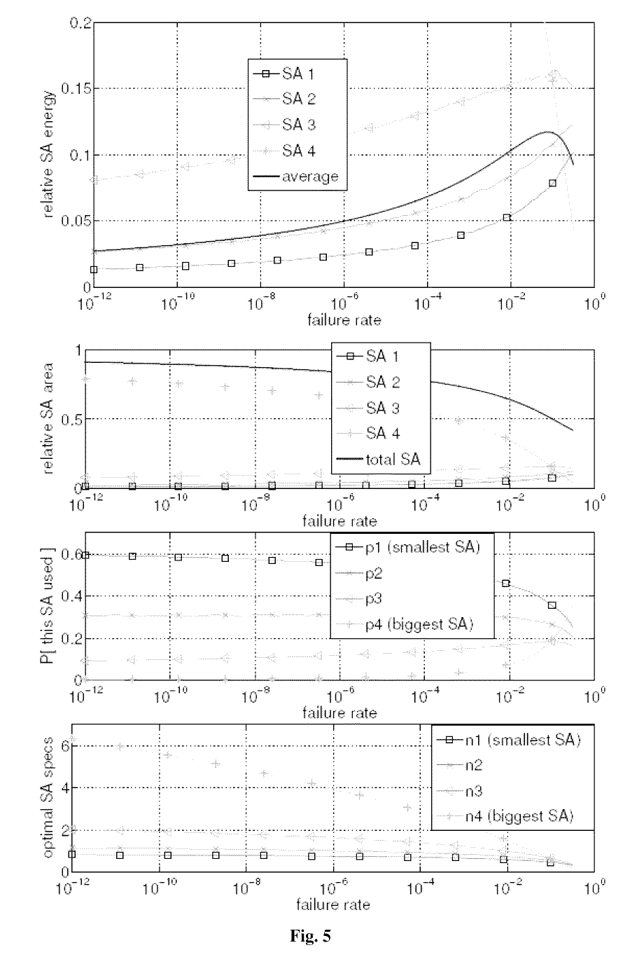

The same exercise was performed for N=4. In this case, a sweep is performed over fᵣ₁, fᵣ₂ and fᵣ₃, and fᵣ₄ is obtained from equation 6. The results are shown in FIG. 5. At fᵣ=10⁻⁹, the relative energy consumption is 0.035, comparable to symmetrical redundancy with N=15 (ignoring overhead).

### b) Results

In the design of FIG. 1b a traditional SA designed for 6σ yield is replaced by a group of 2 SAs. The smaller one is designed for 2σ yield; hence its energy consumption is 9 times smaller than that of the traditional single SA designed for 6σ yield. The bigger SA in a group is designed for 6σ yield. This doublet provides better yield than the single traditional SA, while on average energy consumption is 6 times smaller than that of the single traditional SA. The area overhead of multi-sized SA redundancy compared to traditional SA is 30%. As this design uses extended global bit lines [5], only 1 set of global SAs is required and this area overhead is not a major issue.

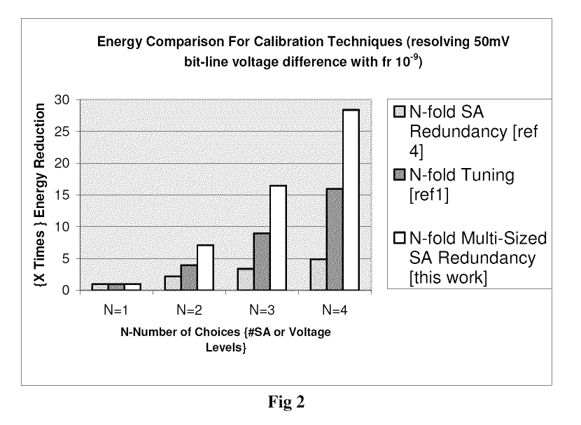

The energy consumption reduction achieved with N multi-sized SA redundancy is much higher compared (FIG. 2) to N fold Symmetric SA redundancy [4].

### c) Example

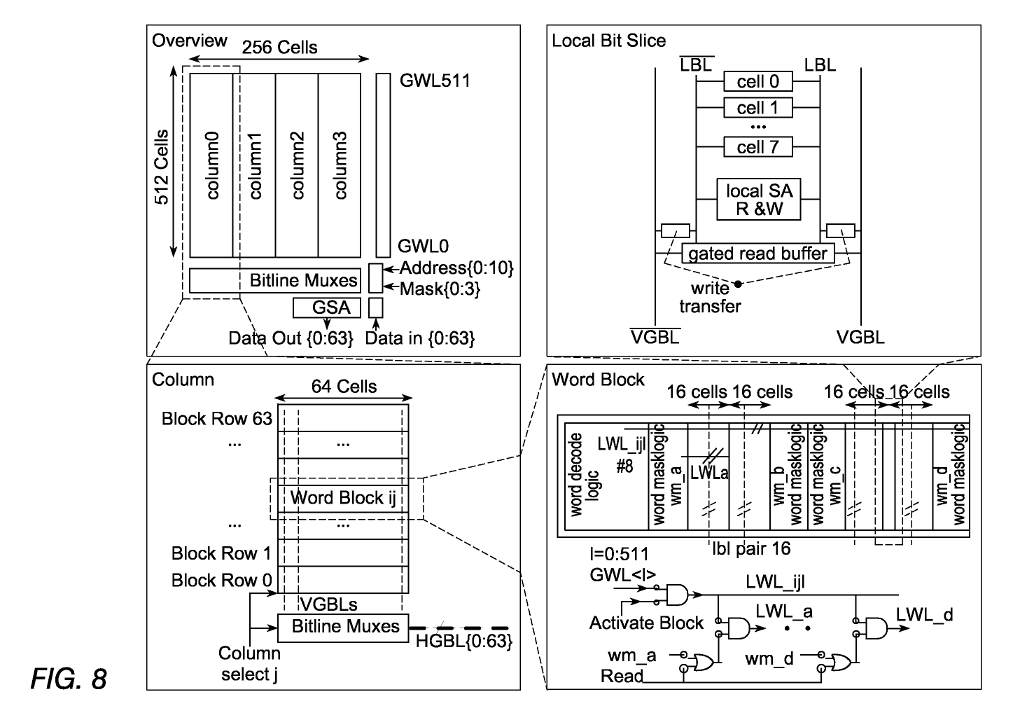

Below, an example of a memory architecture is presented in which the above described principle is applied. The memory matrix consists of 512 by 256 cells. The matrix is divided into 4 columns (FIG. 8). Each column consists of 64 rows of word blocks. The word block consists of 4 masking blocks, each controlling 16 local bit slices. A local bit slice consists of 8 6 T SRAM cells, a local sense amplifier, a gated read buffer, write and pre-charge circuitry. The 11 address bits are decoded with static AND-AND decoders into 512 global word lines (GWLs), 4 column selects (CS) and 8 within block row selects (WBRS). Each row of the memory matrix has its own GWL which is combined with Activate Block signal to generate a local word line (LWL) signal for each individual word.

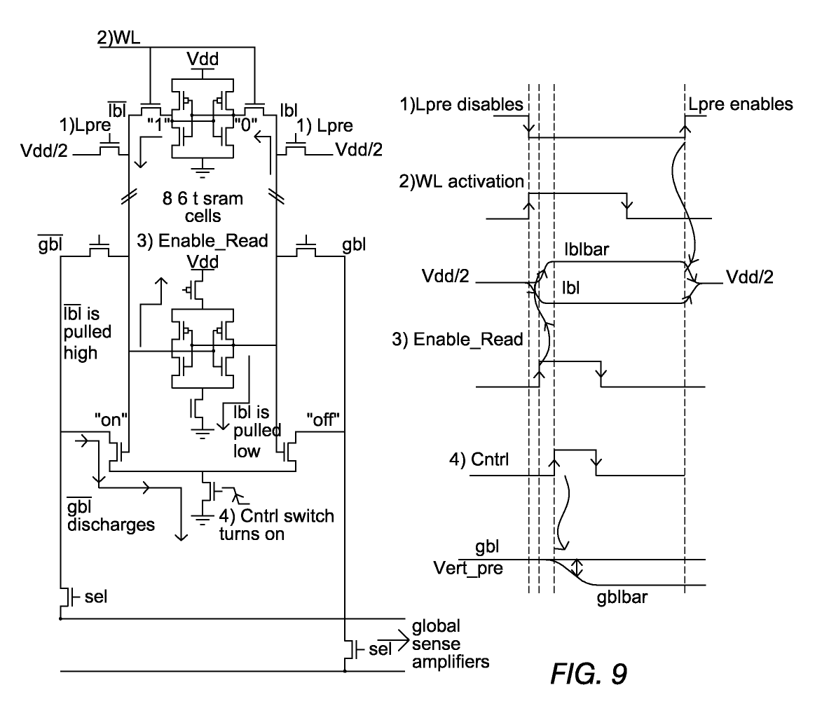

The Local Bit Slice Architecture is shown in the FIG. 9. It consists of 8 SRAM cells, local sense amplifier, gated read buffer, write multiplexer and the local pre-charge

circuitry. The number of SRAM cells (i.e. 8 cells) is selected to achieve minimal energy consumption. The local sense amplifier used during READ operation is also employed as a write receiver during the WRITE operation.

The minimum sized high VT accessed SRAM cell creates a small voltage difference of about 150 mV on the short LBL (FIG. 9). The LSA resolves this voltage difference by pulling the local bit-line for the “0” stored side of the SRAM cell to VSS and the local bit-line for the other side to VDD. Then the gated read buffer is enabled, thereby transferring the local bit-line information to the global bit-line (VGBL) to be sensed by the global sense amplifier (VGSA). The VGBLs are grouped in multiplexed subsets, connected to the VGSA via the bitline multiplexers. The selection which VGBL signal is to be passed on to the VGSA is done using the column select CS. The VDD/2 pre-charged local bitline scheme enables charge re-cycling. The gated read buffer is enabled only for a limited period during the READ operation, reducing the static energy consumption.

In the design of FIG. 8, the high power consumption of SA can be remedied by using the multi-sized SA redundancy (MS-SA-R) of FIG. 1 for the global SA. In particular, a traditional S.A designed for 6σ yield is replaced by a set of 2 SAs. The smaller one is designed for 2σ yield, the bigger SA in a set is designed for 6σ yield.

More in general, there is quadratic relationship between the size (area) of the SAs depending on the desired yield. So a 2σ yield SA is generally 9 times smaller than a 6σ yield SA. For 2 SAs, the relationship can be written as follows:

Sn2=(n2/n1)²×Sn1

wherein
n1=the yield of the smaller sense amplifiers;
n2=the (higher) yield of the larger sense amplifiers;
Sn1=area of the first sense amplifiers, designed for the first yield n1;
Sn2=area of the larger sense amplifiers, designed for the second yield n2.

In case three redundant SAs are used, the relationship becomes:

Sn2=(n2/n1)²×Sn1

Sn3=(n3/n2)²×Sn2

n3>n2>n1

n1×n2×n3=ng

wherein
n3=the (higher) yield of the largest sense amplifiers;
ng=a target yield for the whole redundant group of sense amplifiers;
Sn3=area of the largest sense amplifiers, designed for the third yield n4.

### d) Calibration

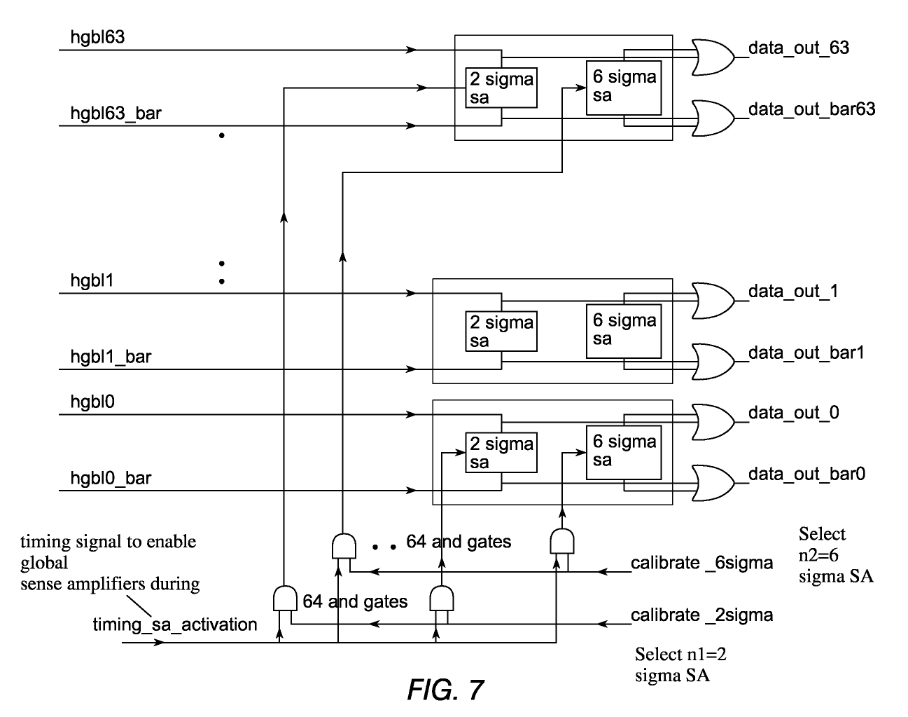

During a calibration phase, it is determined which of the redundant SAs can be used. More particularly, it is desired to use each time the smallest available SA which does not fail. The calibration is done as follows (FIGS. 1 and 7):

Step 1) Initially only the 6-sigma sized SA are selected {Act_{—}6-sigma high} and the data stored is successfully read.

Step 2) Then the 6-sigma sized SA are disabled and all the 2-sigma sized SA are enabled {Act_{—}2-sigma high & Act_{—}6-sigma low} & the READ operation is performed. Failing bit locations are identified. For example, when reading a 64 bit word with bit locations 2, 5, 31, & 64 are erroneous (by comparing with the information read in step 1), then for the doublet numbers 2, 5, 31 & 64 the 6-sigma SA is enabled and for the other doublets the 2-sigma SAs are enabled for READ operations.

Step 3) For the purposes of checking, a READ operation is performed with Act_{—}2-sigma high except for the number 2, 5, 31 & 64 doublets for which Act_{—}6-sigma is made high.

Step 4) If step 3 confirms step 2, then the selection bits will be loaded in the shift register (not shown), which precedes AND selection logic. In the example with the 2-sigma SAs of doublet numbers 2, 5, 31 & 64 failing, this means that the following selection is stored:

(1011011111111111111111111111011111111111111111111111111110)

wherein 0 represents Act_{—}6-sigma high and 1 represents Act_{—}2-sigma high

These values will be used for the memory accesses, till the next calibration phase. The next calibration phase is decided based on the user application. For example, calibration can be triggered if the operating temperature changes by 5° C.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention. The scope of the invention is indicated by the appended claims rather than by the foregoing description. All changes which come within the meaning and range of equivalency of the claims are to be embraced within their scope.

Each of the following references is incorporated herein by reference in its entirety.
[1] S. Cosemans, W. Dehaene, F. Catthoor, “A 3.6 pJ/Access 480 MHz, 128 kb On-Chip SRAM With 850 MHz Boost Mode in 90 nm CMOS With Tunable sense amplifiers,” IEEE J. Solid-State Circuits, pp. 2065-2077, July 2009.
[2] B. D. Yang & L. S. Kim, “A Low-Power SRAM Using Hierarchical Bit Line and Local sense amplifiers,” IEEE J. Solid-State Circuits, pp. 1366-1376, June 2005.
[3] M. J. M. Pelgrom, A. C. J Duinmaijer, A. P. G. Welbers, “Matching properties of MOS transistors,” IEEE J. Solid-State Circuits, pp 1433-1439, October 1989.
[4] N. Verma, A. Chandrakasan, “A 256 kb 65 nm 8 T Subthreshold SRAM employing Sense-Amplifier Redundancy,” IEEE J. Solid-State Circuits pp. 141-149, January 2008.
[5] S. Cosemans, W. Dehaene, F. Catthoor, “A Low-Power Embedded SRAM for Wireless Applications,” IEEE J. Solid-State Circuits, pp. 1607-1617, July 2007.

What is claimed is:

1. A memory circuit comprising:
a plurality of memory cells arranged in rows and columns, each memory cell having an input node and a differential output node;
a plurality of word-lines, each word-line being connected to the input nodes of one row of the memory cells;
a plurality of differential bit-lines, each differential bit-line being connected to the differential output nodes of one column of the memory cells;
a plurality of sense amplifiers connected to the differential bit-lines and configured to amplify a voltage difference sensed on the differential bit-lines, the plurality of sense amplifiers comprising:
a first set of smaller sense amplifiers being of a first size and having a first power consumption and a first failure rate, and
a second set of larger sense amplifiers redundantly arranged to the first set to form redundant groups which each contain one of the smaller sense amplifiers and one of the larger sense amplifiers, the larger sense amplifiers being of a second size and having a second power consumption and a second failure rate, the second size being larger than the first size, the second power consumption being higher than the first power consumption and the second failure rate being lower than the first failure rate,
and
calibration circuitry connected to enable and disable nodes of each of the sense amplifiers and configured to select for each redundant group either the smaller sense amplifier of the first set or, if the smaller sense amplifier fails, the larger sense amplifier of the second set.

2. The memory circuit according to claim 1, wherein the calibration circuitry comprises a register configured to store for each redundant group the selection of the smaller sense amplifier or the larger sense amplifier.

3. The memory circuit according to claim 1, wherein the smaller sense amplifiers of the second set are at least 9 times smaller than the larger sense amplifiers of the first set.

4. The memory circuit according to claim 1, wherein the smaller sense amplifiers of the first set are at least 9 times smaller than the larger sense amplifiers of the first set.

5. The memory circuit according to claim 1, wherein the sense amplifiers meet the following size relationship:
Sn2=(n2/n1)²×Sn1
wherein
n1=a first yield of the smaller sense amplifiers of the first set;
n2=a second yield of the larger sense amplifiers of the second set;
Sn1=an area of the smaller sense amplifiers of the first set, designed for the first yield n1;
Sn2=an area of the larger sense amplifiers of the second set, designed for the second yield n2.

6. The memory circuit according to claim 1, wherein each of the redundant groups of sense amplifiers is connected to one of the plurality of differential bit-lines.

7. The memory circuit according to claim 1, wherein each of the redundant groups of sense amplifiers is connected to a multiplexed subset of the plurality of differential bit-lines.

8. A memory circuit comprising:
a plurality of memory cells arranged in rows and columns, each memory cell having an input node and a differential output node;
a plurality of word-lines, each word-line being connected to the input nodes of one row of the memory cells;
a plurality of differential bit-lines, each differential bit-line being connected to the differential output nodes of one column of the memory cells,
a plurality of redundant groups of sense amplifiers of different sizes, the sense amplifiers of each redundant group being all connected to the same differential bit-line and being provided for amplifying a voltage difference sensed on the differential bit-line, each of the redundant groups of sense amplifiers comprising:
a first sense amplifier of a first size defining a first power consumption and a first failure rate, and
a second sense amplifier of a second size larger than the first size, defining a second power consumption higher than the first power consumption and a second failure rate lower than the first failure rate,
and
calibration circuitry connected to enable and disable nodes of each of the sense amplifiers and configured to select for each of the redundant groups the first sense amplifier or, if the first sense amplifier fails, the second sense amplifier.

9. The memory circuit according to claim 8, wherein the calibration circuitry comprises a register for storing for each redundant group the selection of the first sense amplifier or the second sense amplifier.

10. The memory circuit according to claim 8, wherein the sense amplifiers meet the following size relationship:
Sn2=(n2/n1)²×Sn1
wherein
n1=a first yield of the first sense amplifiers;
n2=a second yield of the second sense amplifiers, higher than the first yield;
Sn1=an area of the first sense amplifiers of the first set, designed for the first yield n1;
Sn2=an area of the larger sense amplifiers of the second set, designed for the second yield n2.

11. the memory circuit according to claim 8, wherein each of the redundant groups of sense amplifiers is connected to one of the plurality of differential bit-lines.

12. The memory circuit according to claim 8, wherein each of the redundant groups of sense amplifiers is connected to a multiplexed subset of the plurality of differential bit-lines.

13. The memory circuit according to claim 8, wherein each of the redundant groups of sense amplifiers further comprises a third sense amplifier of a third size larger than the second size, defining a third power consumption higher than the second power consumption, and a third failure rate lower than the second failure rate, and wherein the calibration circuitry is further configured to select for each group the third sense amplifier if the first and second sense amplifiers fail.

14. The memory circuit according to claim 13, wherein the calibration circuitry comprises a register for storing for each group the selection of the first, second or third sense amplifier.

15. The memory circuit according to claim 13, wherein the sense amplifiers meet the following size relationship:
Sn2=(n2/n1)²×Sn1
Sn3=(n3/n2)²×Sn2
n3>n2>n1
n1×n2×n3=ng
wherein
n1=a first yield of the first sense amplifiers;
n2=a second yield of the second sense amplifiers;
n3=a third yield of the third sense amplifiers;
ng=a target yield for each redundant group of sense amplifiers;
Sn1=an area of the first sense amplifiers, designed for the first yield n1;
Sn2=an area of the second sense amplifiers, designed for the second yield n2;
Sn3=an area of the third sense amplifiers, designed for the third yield n3.

16. The memory circuit according to claim 13, wherein each of the redundant groups of sense amplifiers is connected to one of the plurality of differential bit-lines.

17. The memory circuit according to claim 13, wherein each of the redundant groups of sense amplifiers is connected to a multiplexed subset of the plurality of differential bit-lines.

18. The memory circuit according to claim 13, wherein each of the redundant groups of sense amplifiers further comprises a fourth sense amplifier of a fourth size larger than the third size, defining a fourth power consumption higher than the third power consumption, and a fourth failure rate lower than the third failure rate, and wherein the calibration circuitry is further configured to select for each group the fourth sense amplifier if the first, second and third sense amplifiers fail.

19. The memory circuit according to claim 18, wherein the calibration circuitry comprises a register for storing for each group the selection of the first, second, third or fourth sense amplifier.

20. The memory circuit according to claim 18, wherein the sense amplifiers meet the following size relationship:
Sn2=(n2/n1)²×Sn1
Sn3=(n3/n2)²×Sn2
Sn4=(n4/n3)²×Sn3
n4>n3>n2>n1
n1×n2×n3×n4=ng
wherein
n1=a first yield of the first sense amplifiers;
n2=a second yield of the second sense amplifiers;
n3=a third yield of the third sense amplifiers;
n4=a fourth yield of the fourth sense amplifiers;
ng=a target yield for each redundant group of sense amplifiers;
Sn1=an area of the first sense amplifiers, designed for the first yield n1;
Sn2=an area of the second sense amplifiers, designed for the second yield n2;
Sn3=an area of the third sense amplifiers, designed for the third yield n3;
Sn4=an area of the fourth sense amplifiers, designed for the fourth yield n4.

21. The memory circuit according to claim 18, wherein each of the redundant groups of sense amplifiers is connected to one of the plurality of differential bit-lines.

22. The memory circuit according to claim 18, wherein each of the redundant groups of sense amplifiers is connected to a multiplexed subset of the plurality of differential bit-lines.
